(19) United States
(12) Patent Application Publication
(10) Pub. No.: US 2025/0169110 A1
(43) Pub. Date: May 22, 2025

(54) ELECTRONIC DEVICE

(71) Applicant: Innolux Corporation, Miaoli County (TW)

(72) Inventors: Cheng-Hsu Chou, Miaoli County (TW); I-Ho Shen, Miaoli County (TW); Chih-Hsiung Chang, Miaoli County (TW)

(73) Assignee: Innolux Corporation, Miaoli County (TW)

(21) Appl. No.: 18/922,253

(22) Filed: Oct. 21, 2024

(30) Foreign Application Priority Data
Nov. 20, 2023 (CN) 202311548145.0

(51) Int. Cl. H01L 29/786; H01L 27/12; H01L 29/423

(52) U.S. Cl. CPC H10D 30/6734; H10D 30/673; H10D 64/518; H10D 86/40; H10D 86/60

(57) ABSTRACT

An electronic device including a substrate and an electronic element is provided. The electronic element is disposed on the substrate and includes a first gate electrode, a semiconductor pattern, a source electrode, a drain electrode and a second gate electrode. The semiconductor pattern includes an overlapping region, a first side region and a second side region. A portion of the semiconductor pattern overlapped with the first gate electrode is defined as the overlapping region. The first side region and the second side region are respectively connected to two opposite sides of the overlapping region in a first direction and respectively include two opposite first edges of the semiconductor pattern. The source electrode and the drain electrode are respectively electrically connected to the first side region and the second side region. At least a portion of the second gate electrode is overlapped with the second side region of the semiconductor pattern.

### CROSS-REFERENCE TO RELATED APPLICATION

This application claims the priority benefit of China application serial no. 202311548145.0, filed on Nov. 20, 2023. The entirety of the above-mentioned patent application is hereby incorporated by reference herein and made a part of this specification.

### BACKGROUND

### Technical Field

The disclosure relates to an electronic device, and more particularly, to an electronic device with two gate electrodes of different sizes.

### Description of Related Art

At present, there are more and more products with thin film transistors being applied to high-voltage operations (such as electrophoretic displays, antenna devices, etc.). However, as an operating voltage increases, the thin film transistors face problems such as increased leakage current and size increase.

### SUMMARY

The disclosure provides an electronic device, which helps to improve an issue of leakage current or size increase.

In an embodiment of the disclosure, the electronic device includes a substrate and an electronic element. The electronic element is disposed on the substrate and includes a first gate electrode, a semiconductor pattern, a source electrode, a drain electrode and a second gate electrode. The semiconductor pattern includes an overlapping region, a first side region and a second side region. A portion of the semiconductor pattern overlapped with the first gate electrode is defined as the overlapping region. The first side region and the second side region are respectively connected to two opposite sides of the overlapping region in a first direction. The first side region and the second side region respectively include two opposite first edges of the semiconductor pattern. The source electrode and the drain electrode are respectively electrically connected to the first side region and the second side region. At least a portion of the second gate electrode is overlapped with the second side region of the semiconductor pattern.

In order for the aforementioned features and advantages of the disclosure to be more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic top view of an electronic device according to an embodiment of the disclosure.

FIG. 2 is a schematic partial cross-sectional view of an electronic device according to an embodiment of the disclosure.

FIG. 3 is a schematic partial top view corresponding to the embodiment of FIG. 2.

FIG. 4 is a schematic partial cross-sectional view of an electronic device according to another embodiment of the disclosure.

FIG. 5 and FIG. 6 are respectively two schematic partial top views corresponding to the embodiment of FIG. 4.

FIG. 7 is a schematic partial cross-sectional view of an electronic device according to still another embodiment of the disclosure.

FIG. 8 is a schematic partial top view corresponding to the embodiment of FIG. 7.

FIG. 9 is a schematic partial cross-sectional view of an electronic device according to yet another embodiment of the disclosure.

FIG. 10 is a partial top view corresponding to the embodiment of FIG. 9

FIG. 11 to FIG. 16 are respectively schematic partial cross-sectional views of electronic devices according to other embodiments of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Certain terms are used throughout the specification of the disclosure and the appended claims to refer to specific components. Those skilled in the art should understand that electronic device manufacturers may probably use different names to refer to the same components. This specification is not intended to distinguish between components that have the same function but different names. In the following specification and claims, the terms “including”, “containing”, etc., are open terms, so that they should be interpreted as meaning of “including but not limited to . . . “.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

One structure (or layer, component, or substrate) described in this disclosure is located on/above another structure (or layer, component, or substrate), which may mean that the two structures are adjacent and directly connected, or it may mean that the two structures are adjacent and are indirectly connected. Indirect connection means that there is at least one intermediary structure (or intermediary layer, intermediary component, intermediary substrate, or intermediary spacer) between the two structures, a lower surface of one structure is adjacent to or directly connected to an upper surface of the intermediary structure, and an upper surface of another structure is adjacent to or directly connected to a lower surface of the intermediate structure. The intermediary structure may be composed of a single-layer or multi-layer physical structures or a non-physical structure, which is not limited by the disclosure. In the disclosure, when a structure is disposed “on” another structure, it may mean that the structure is “directly” on the other structure, or that the structure is “indirectly” on the other structure, i.e., at least one structure is further sandwiched between the structure and the other structure.

The terms “about”, “equal to”, “equivalent” or “identical”, “substantially” or “approximately” are generally interpreted as being within a range of 20% of a given value or range, or as being within a range of 10%, 5%, 3%, 2%, 1%, or 0.5% of the given value or range. In addition, the terms “a range is a first value to a second value” and “a range is between a first value and a second value” mean that the range includes the first value, the second value and other values therebetween.

The ordinal numbers used in the specification and claims, such as “first”, “second”, etc., are used to modify components, and do not imply and represent the component or these components have any previous ordinal numbers, and do not represent a sequence of one component with another, or a sequence in a manufacturing method.

The use of these ordinal numbers is only to make a clear distinction between a component with a certain name and another component with the same name. The same terms may not be used in the claims and the specification, and accordingly, a first component in the specification may be a second component in the claims.

The electrical connection or coupling described in the disclosure may refer to direct connection or indirect connection. In the case of direct connection, terminals of components on the two circuits are directly connected or connected to each other by a conductor line segment, and in the case of indirect connection, there are switches, diodes, capacitors, inductors, resistors, other suitable components, or a combination of the above components between the terminals of the components on the two circuits, but the disclosure is not limited thereto.

In the disclosure, thickness, length and width may be measured by using an optical microscope, and the thickness or width may be measured through a cross-sectional image in an electron microscope, but the disclosure is not limited thereto. In addition, any two values or directions used for comparison may have certain errors. In addition, the terms “equal to”, “equivalent”, “the same”, “substantially” or “approximately” mentioned in this disclosure generally mean falling within 10% of a given value or range. Moreover, the terms “a given range is a first value to a second value”, “a given range falls within a range of a first value to a second value” or “a given range is between a first value and a second value” means that the given range includes the first value, the second value and other values therebetween. If a first direction is perpendicular to a second direction, an angle between the first direction and the second direction may be between 80 degrees and 100 degrees; and if the first direction is parallel to the second direction, the angle between the first direction and the second direction may be between 0° and 10°.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the disclosure, an electronic device may include a display device, a backlight device, an antenna device, a sensing device or a splicing device, but the disclosure is not limited thereto. The electronic device may be a bendable or flexible electronic device. The display device may be a non-self-luminous display device or a self-luminous display device. The display device may include, for example, liquid crystal, light-emitting diodes, fluorescence, phosphor, quantum dots (QD), other suitable display media, or a combination of the above. The antenna device may include, for example, a frequency selective surface (FSS), a radio frequency filter (RF-filter), a polarizer, a resonator, or an antenna, etc. The antenna may be a liquid crystal type antenna or a non-liquid crystal type antenna. The sensing device may be a sensing device capable of sensing capacitance, light, heat energy or ultrasonic waves, but the disclosure is not limited thereto. In the disclosure, the electronic device may include electronic components, and the electronic components may include passive components and active components, such as capacitors, resistors, inductors, diodes, transistors, etc. Diodes may include light-emitting diodes or photodiodes. The light-emitting diodes may include, for example, organic light-emitting diodes (OLEDs), mini LEDs, micro LEDs or quantum dot LEDs, but the disclosure is not limited thereto. The splicing device may be, for example, a display splicing device or an antenna splicing device, but the disclosure is not limited thereto. It should be noted that the electronic device may be any combination of the above, but the disclosure is not limited thereto. In addition, a shape of the electronic device may be a rectangular shape, a circular shape, a polygonal shape, a shape with curved edges, or other suitable shapes. The electronic device may have peripheral systems such as a driving system, a control system, and a light source system to support display devices, antenna devices, wearable devices (for example, including augmented reality or virtual reality), vehicle-mounted devices (for example, including vehicle windshields), or splicing devices.

It should be noted that in the embodiments shown below, features in several different embodiments may be replaced, reorganized, and mixed without departing from the spirit of the disclosure to complete other embodiments. Features in various embodiments may be mixed and matched as long as they do not violate the spirit of the disclosure or conflict with each other.

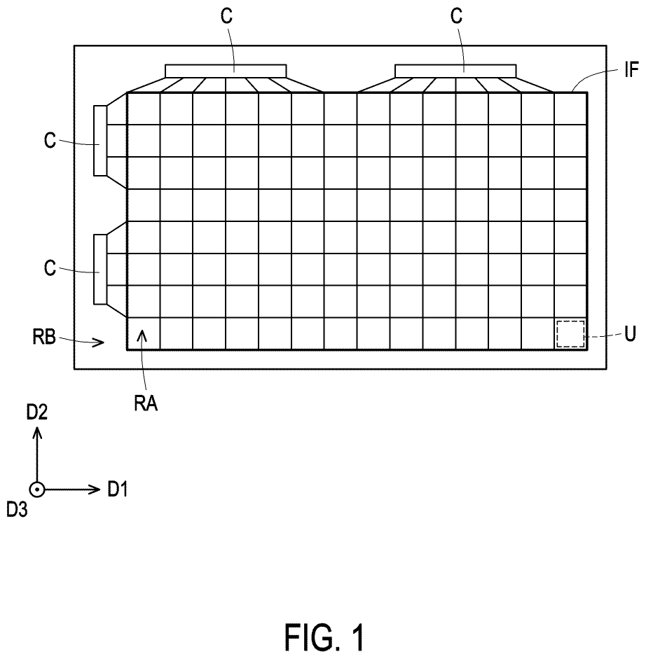

FIG. 1 is a schematic top view of an electronic device according to an embodiment of the disclosure. Referring to FIG. 1, the electronic device may include an active area RA and a peripheral area RB. The peripheral area RB may be located on at least one side of the active area RA. In some embodiments, as shown in FIG. 1, the peripheral area RB may surround the active area RA, but the disclosure is not limited thereto. In FIG. 1, the interface IF between the active area RA and the peripheral area RB is marked with a thick solid line to facilitate the distinction between the active area RA and the peripheral area RB. According to some embodiments, a substrate 10 may include the active area RA and the peripheral area RB.

A plurality of units U (one is schematically marked in FIG. 1) may be disposed in the active area RA. The plurality of units U may be arranged in an array in a first direction D1 and a second direction D2. A device type in the unit U may vary according to the application of the electronic device. For example, if the electronic device is used as a display device, the unit U may include a display element and a switching element, but the disclosure is not limited thereto. On the other hand, if the electronic device is used as an antenna device, the unit U may include an antenna structure and a switching element, but the disclosure is not limited thereto.

A plurality of driving circuits C may be disposed in the peripheral area RB. The plurality of driving circuits C are electrically connected to the plurality of units U in the active area RA. For example, the plurality of driving circuits C may be electrically connected to the plurality of units U in the active area RA through a plurality of conductive lines (not indicated). The driving circuit C may include active elements, passive elements, or a combination of the above, but the disclosure is not limited thereto. The plurality of conductive lines may include conductive lines (for example, scan lines) extending along the first direction D1 and conductive lines (for example, data lines) extending along the second direction D2. The electronic elements including a semiconductor pattern, a first gate electrode and a second gate electrode described later may be implemented as the switching elements in the units U or the active elements in the driving circuit C, which will not be repeated below.

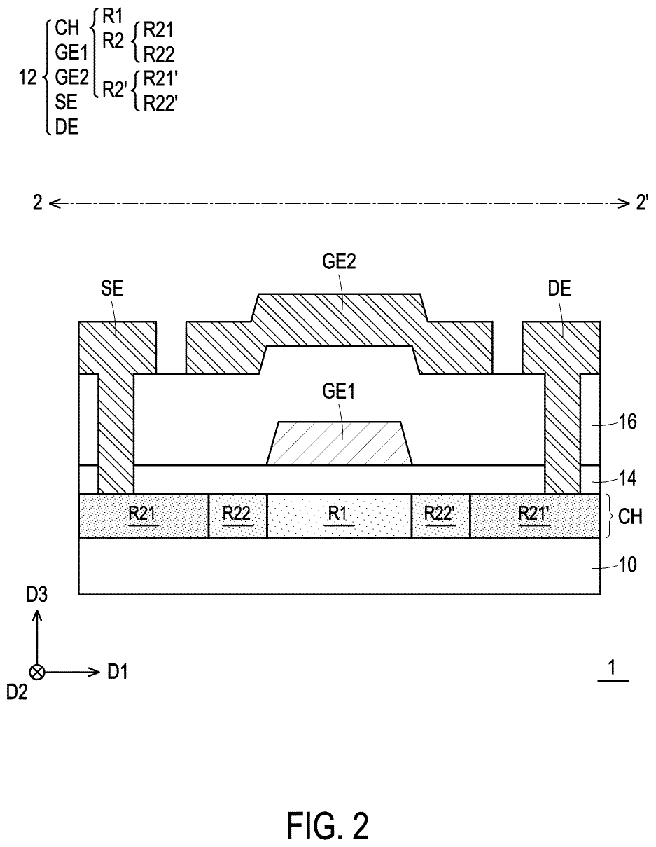

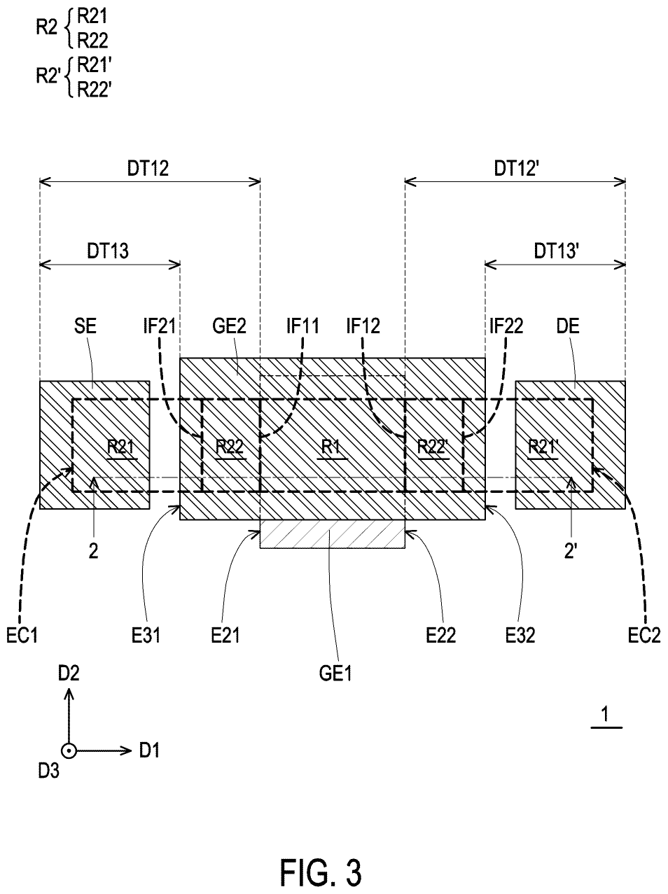

FIG. 2 is a schematic partial cross-sectional view of an electronic device according to an embodiment of the disclosure. FIG. 3 is a schematic partial top view corresponding to the embodiment of FIG. 2, where FIG. 2 may be referred for a cross-sectional view along a section line 2-2′ in FIG. 3, and FIG. 3 only schematically illustrates a semiconductor pattern and a first gate electrode, a second gate electrode, a source electrode and a drain electrode.

Referring to FIG. 2 and FIG. 3, an electronic device 1 may include a substrate 10 and electronic element 12. The electronic element 12 is disposed on the substrate 10. The electronic element 12 may be, for example, a switching element in the aforementioned unit U or an active element in the aforementioned driving circuit C, which is not limited by the disclosure. According to some embodiments, the electronic element 12 may be disposed in the peripheral area RB. According to some embodiments, the electronic element 12 may be disposed in the active area RA. The electronic element 12 includes a first gate electrode GE1, a semiconductor pattern CH, a source electrode SE, a drain electrode DE and a second gate electrode GE2. The semiconductor pattern CH includes an overlapping region R1, a first side region R2, and a second side region R2′. A portion of the semiconductor pattern CH overlapped with the first gate electrode GE1 is defined as the overlapping region R1. In the first direction D1, the first side region R2 and the second side region R2′ are respectively connected to two opposite sides of the overlapping region R1. The first side region R2 and the second side region R2′ respectively include two opposite first edges (for example, a first edge EC1 and a first edge EC2) of the semiconductor pattern CH. The source electrode SE and the drain electrode DE are respectively electrically connected to the first side region R2 and the second side region R2′. At least a portion of the second gate electrode GE2 is overlapped with the second side region R2′ of the semiconductor pattern CH. FIG. 3 is a top view showing a plane formed by the first direction D1 and the second direction D2. FIG. 2 is a cross-sectional view, and a thickness of each layer in FIG. 2 is a thickness along a third direction D3. The first direction D1, the second direction D2, and the third direction D3 are different directions. For example, the first direction D1, the second direction D2, and the third direction D3 may be perpendicular to each other.

Specifically, the substrate 10 may be a rigid substrate or a flexible substrate. A material of the substrate 10 includes, for example, glass, quartz, ceramic, sapphire or plastic, but the disclosure is not limited thereto. Plastic may include polycarbonate (PC), polyimide (PI), polypropylene (PP), polyethylene terephthalate (PET), other suitable flexible materials or combinations of the aforementioned materials, but the disclosure is not limited thereto. In addition, a light transmittance of the substrate 10 is not limited by the disclosure, i.e., the substrate 10 may be a light-transmitting substrate, a semi-light-transmitting substrate or an opaque substrate.

The electronic element 12 is, for example, an active element, such as a low-temperature polycrystalline silicon (LTPS) N-metal-oxide-semiconductor (NMOS) thin film transistor (TFT), but the disclosure is not limited thereto.

The semiconductor pattern CH is disposed on the substrate 10 and is, for example, located between the first gate electrode GE1 and the substrate 10. A material of the semiconductor pattern CH includes, for example, amorphous silicon, polysilicon or metal oxide, but the disclosure is not limited thereto. The metal oxide may be, for example, indium gallium zinc oxide (IGZO). For example, the overlapping region R1 of the semiconductor pattern CH may be a channel region (i.e., the region of the semiconductor pattern CH overlapped with the first gate electrode GE1 in the third direction D3), and the first side region R2 and the second side region R2′ of the semiconductor pattern CH may respectively include an N-type highly doped region (such as an N-type highly doped region R21 and an N-type highly doped region R21′) and an N-type lightly doped region (such as an N-type lightly doped region R22 and an N-type lightly doped region R22′) located between the overlapping region R1 and the N-type highly doped region, and the second gate electrode GE2 is at least overlapped with the N-type lightly doped region (for example, at least overlapped with the N-type lightly doped region R22′) of the second side region R2′. Taking FIG. 2 and FIG. 3 as an example, the second gate electrode GE2 may extend from above the overlapping region R1 towards above the N-type highly doped regions (including the N-type highly doped region R21 and the N-type highly doped region R21′), so that in a length direction of the semiconductor pattern CH (such as the first direction D1), an edge of the second gate electrode GE2 is closer to the edge of the semiconductor pattern CH than an edge of the first gate electrode GE1.

The first gate electrode GE1 and the second gate electrode GE2 may have different sizes. Specifically, according to some embodiments, as shown in FIG. 3, in the first direction D1, the first gate electrode GE1 has two opposite second edges (such as a second edge E21 and a second edge E22), and the second gate electrode GE2 has two opposite third edges (such as a third edge E31 and a third edge E32). On a single side of the semiconductor pattern, taking a semiconductor edge of the semiconductor pattern on that side as a reference, a distance between the second gate electrode and the semiconductor edge is less than a distance between the first gate electrode and the same semiconductor edge. In detail, on a single side of the semiconductor pattern (for example, a left side in FIG. 3), taking the semiconductor edge of the semiconductor pattern on that side (such as the first edge EC1) as a reference, a distance DT13 between the third edge E31 of the second gate electrode GE2 and the corresponding first edge EC1 of the semiconductor pattern CH is less than a distance DT12 between the second edge E21 of the first gate electrode GE1 and the corresponding first edge EC1 of the semiconductor pattern CH. On the other side of the semiconductor pattern (for example, the right side in FIG. 3), taking the semiconductor edge of the semiconductor pattern on the other side (such as the first edge EC2) as a reference, a distance DT13′ between the third edge E32 of the second gate electrode GE2 and the corresponding first edge EC2 of the semiconductor pattern CH is less than a distance DT12′ between the second edge E22 of the first gate electrode GE1 and the corresponding first edge EC2 of the semiconductor pattern CH.

In FIG. 3, the third edge E31 of the second gate electrode GE2 exceeds an interface IF21 between the N-type highly doped region R21 and the N-type lightly doped region R22, and the third edge E31 is located between the interface IF21 and the first edge EC1 of the semiconductor pattern CH. In addition, the third edge E32 of the second gate electrode GE2 exceeds an interface IF22 between the N-type highly doped region R21′ and the N-type lightly doped region R22′, and the third edge E32 is located between the interface IF22 and the first edge EC2 of the semiconductor pattern CH. However, the positions of the third edge E31 and the third edge E32 of the second gate electrode GE2 are not limited thereto. In other embodiments, although not shown, the third edge E31 may not exceed the interface IF21, for example, the third edge E31 may be located between the interface IF21 and the interface IF11 between the overlapping region R1 and the N-type lightly doped region R22, or the third edge E31 may be aligned with the interface IF21. In addition, the third edge E32 may not exceed the interface IF22, for example, the third edge E32 may be located between the interface IF22 and the interface IF12 between the overlapping region R1 and the N-type lightly doped region R22′, or the third edge E32 may be aligned with the interface IF22.

In some embodiments, as shown in FIG. 2, the electronic device 1 may further include a first dielectric layer 14. The first dielectric layer 14 is disposed between the semiconductor pattern CH and the first gate electrode GE1. A material of the first dielectric layer 14 includes, for example, an organic insulating material, an inorganic insulating material or a combination thereof. The organic insulating material includes, for example, polymethylmethacrylate (PMMA), epoxy, acrylic-based resin, silicone, polyimide polymer, or a combination thereof, but the disclosure is not limited thereto. The inorganic insulating material includes, for example, silicon oxide or silicon nitride, but the disclosure is not limited thereto.

The first gate electrode GE1 is, for example, disposed on the first dielectric layer 14 and located above the overlapping region R1. In some embodiments, the second edge E21 and the second edge E22 of the first gate electrode GE1 may be respectively aligned with the interface IF11 and the interface IF12, but the disclosure is not limited thereto. A material of the first gate electrode GE1 includes, for example, metal or metal stacked layers, such as aluminum, molybdenum or titanium/aluminum/titanium, but the disclosure is not limited thereto.

In some embodiments, as shown in FIG. 2, the electronic device 1 may further include a second dielectric layer 16. The second dielectric layer 16 is disposed on the first dielectric layer 14 and the first gate electrode GE1 and is, for example, located between the first gate electrode GE1 and the second gate electrode GE2. A material of the second dielectric layer 16 includes, for example, an organic insulating material, an inorganic insulating material or a combination thereof.

The second gate electrode GE2 is, for example, disposed on the second dielectric layer 16 and in the top view, at least a portion of the second gate electrode GE2 is located between the first gate electrode GE1 and the drain electrode DE. Taking FIG. 3 as an example, the second gate electrode GE2 may cover the overlapping region R1, the N-type lightly doped region R22, the N-type lightly doped region R22′, a part of the N-type high-doped region R21, and a part of the N-type high-doped region R21′, but the disclosure is not limited thereto. A material of the second gate electrode GE2 includes, for example, metal or metal stacked layers, such as aluminum, molybdenum or titanium/aluminum/titanium, but the disclosure is not limited thereto.

The source electrode SE and the drain electrode DE are, for example, disposed on the second dielectric layer 16, and the second gate electrode GE2, the source electrode SE and the drain electrode DE, for example, belong to a same conductive layer. Specifically, the electronic element 12 may include a conductive layer, and the conductive layer includes the second gate electrode GE2, the source electrode SE, and the drain electrode DE. As shown in FIG. 2, the source electrode SE may penetrate through the first dielectric layer 14 and the second dielectric layer 16 to be electrically connected to the N-type highly doped region R21. In addition, the drain electrode DE may penetrate through the first dielectric layer 14 and the second dielectric layer 16 to be electrically connected to the N-type highly doped region R21′.

Through the arrangement of the second gate electrode GE2, a leakage current may be reduced without significantly reducing a conduction current (Ion) of the electronic element 12. In detail, taking the LTPS NMOS TFT as an example, when the electronic element 12 is in a turn-off state (for example, when a voltage of the first gate electrode GE1 is less than zero), by making a voltage of the second gate electrode GE2 to be less than zero, electrons accumulated on an upper surface (a surface facing the first gate electrode GE1) of the N-type lightly doped region (including the N-type lightly doped region R22 and the N-type lightly doped region R22′) may be reduced, which may increase a resistance of the N-type lightly doped region and help reducing the leakage current of the electronic element 12. On the other hand, when the electronic element 12 is in a turn-on state (for example, when the voltage of the first gate electrode GE1 is greater than zero), by making the voltage of the second gate electrode GE2 to be greater than zero, electrons are induced to accumulate on the upper surface of the N-type lightly doped region, which reduces the resistance of the N-type lightly doped region and helps to increase the conduction current of the electronic element 12.

Under the framework of FIG. 2, the first gate electrode GE1 and the semiconductor pattern CH are separated by the first dielectric layer 14, and the second gate electrode GE2 and the semiconductor pattern CH are separated by the first dielectric layer 14 and the second dielectric layer 16. Namely, an influence of the first gate electrode GE1 on carriers in the semiconductor pattern CH is related to a thickness and dielectric constant of the first dielectric layer 14, while an influence of the second gate electrode GE2 on the carriers in the semiconductor pattern CH is not only related to the thickness and dielectric constant of the first dielectric layer 14, but also related to a thickness and dielectric constant of the second dielectric layer 16. In some embodiments, an absolute value of the voltage applied to the second gate electrode GE2 is, for example, greater than or equal to an absolute value of the voltage applied to the first gate electrode GE1.

The electronic device may be a high cross-voltage product. According to some embodiments, a voltage across the source electrode and the drain electrode in an electronic device may be between 8 volts and 70 volts, such as between 10 volts and 60 volts, between 15 volts and 50 volts, between 20 volts to 50 volts, and for example, greater than 10 volts. When electronic element 12 is applied to products of high voltage operations (such as a voltage across the source electrode SE and the drain electrode DE is greater than 10 volts), such as applied to an electrophoretic display or an antenna device, the configuration of the second gate electrode GE2 helps to miniaturize the electronic element 12. In detail, taking the LTPS NMOS TFT as an example, when the electronic element 12 is in the turn-off state (for example, when the voltage of the first gate electrode GE1 is less than zero) or in the turn-on state (for example, when the voltage of the first gate electrode GE1 is greater than zero), by making the voltage of the second gate electrode GE2 to be less than zero, the resistance of the N-type lightly doped region (including the N-type lightly doped region R22 and the N-type lightly doped region R22′) may be increased, thereby reducing the effectiveness of a channel region electric field and improving a voltage tolerance of the electronic element 12. In this way, there is no need to increase the voltage tolerance of the electronic element 12 by increasing a length of the N-type lightly doped region in the first direction D1, which helps to the miniaturize the electronic element 12.

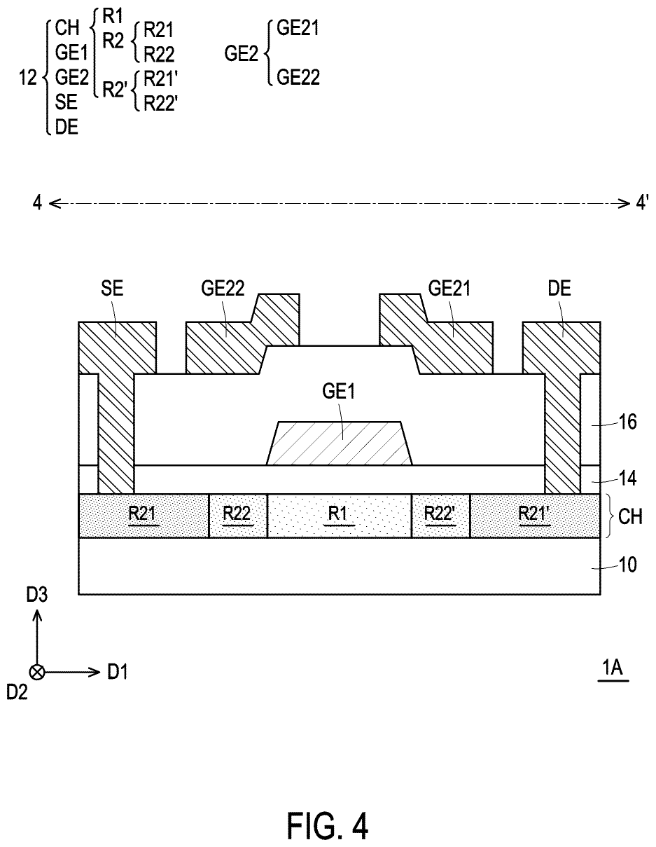

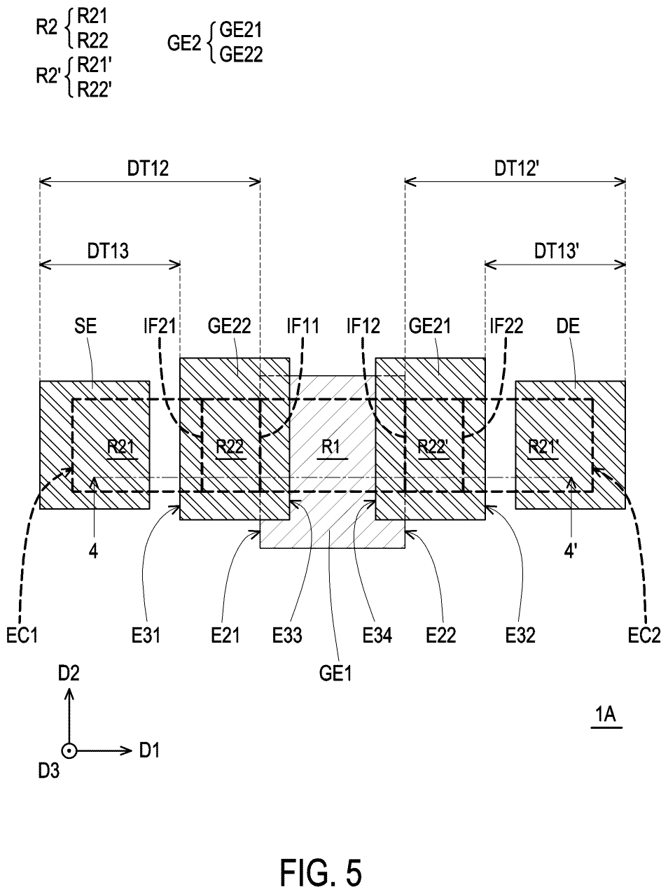

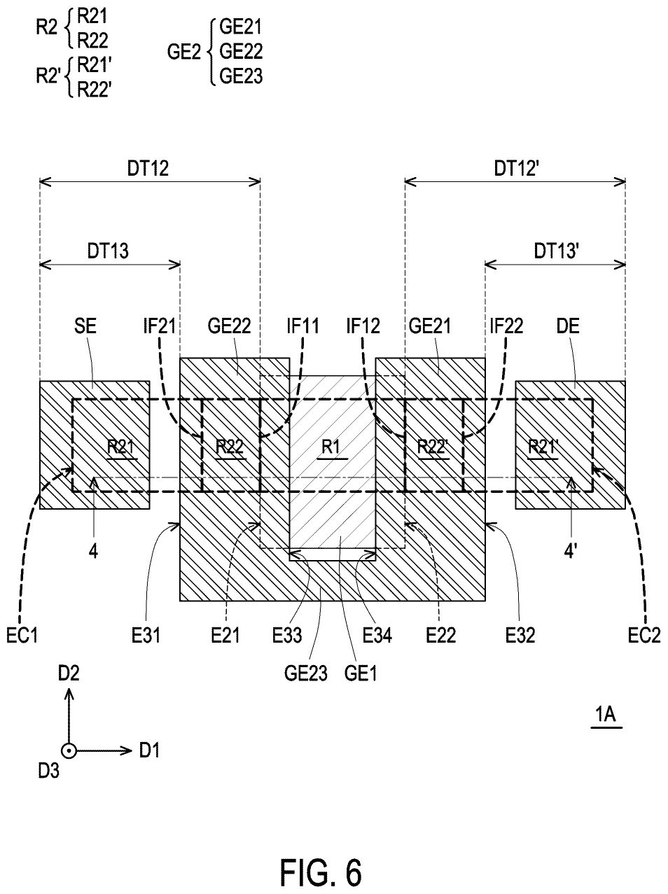

FIG. 4 is a schematic partial cross-sectional view of an electronic device according to another embodiment of the disclosure. FIG. 5 and FIG. 6 are respectively two schematic partial top views corresponding to the embodiment of FIG. 4. FIG. 4 may be referred for the cross-sectional views along a section line 4-4′ in FIG. 5 and FIG. 6, and FIG. 5 and FIG. 6 only schematically illustrate a semiconductor pattern, a first gate electrode, a second gate electrode, a source electrode and a drain electrode in FIG. 4.

In some embodiments, as shown in an electronic device 1A of FIG. 4 and FIG. 5, the second gate electrode GE2 may include a first branch portion GE21 and a second branch portion GE22. In the top view, as shown in FIG. 5, a portion of the first branch portion GE21 may be disposed between the first gate electrode GE1 and the drain electrode DE, and a portion of the second branch portion GE22 may be disposed between the first gate electrode GE1 and the source electrode SE. The first branch portion GE21 and the second branch portion GE22 may be electrically independent or electrically connected. In some embodiments, as shown in FIG. 6, the second gate electrode GE2 may further include a connecting portion GE23, where the first branch portion GE21 and the second branch portion GE22 of the second gate electrode GE2 are connected through the connecting portion GE23. In the top view, the first branch portion GE21, the second branch portion GE22 and the connecting portion GE23 form a recess portion (such as a U-shaped second gate electrode GE2). An extending direction of the recess portion is, for example, parallel to the second direction D2.

In the electronic device FIG. 1A, by reducing an overlapping area of the first gate electrode GE1 and the second gate electrode GE2, a stray capacitance between the first gate electrode GE1 and the second gate electrode GE2 may be reduced, thereby helping to reduce a signal interference between the first gate electrode GE1 and the second gate electrode GE2.

In FIG. 5 and FIG. 6, the third edge E31 of the second gate electrode GE2 is located between the interface IF21 and the first edge EC1 of the semiconductor pattern CH, the third edge E32 of the second gate electrode GE2 is located between the interface IF22 and the first edge EC2 of the semiconductor pattern CH, the third edge E33 of the second gate electrode GE2 is located between the interface IF11 and the third edge E34 of the second gate electrode GE2, and the third edge E34 of the second gate electrode GE2 is located between the interface IF12 and the third edge E33 of the second gate electrode GE2. However, positions of the third edge E31, the third edge E32, the third edge E33 and the third edge E34 of the second gate electrode GE2 are not limited thereto. In other embodiments, although not shown, the third edge E31 may be located between the interface IF11 and the interface IF21 or aligned with the interface IF21. The third edge E32 may be located between the interface IF12 and the interface IF22 or aligned with the interface IF22. The third edge E33 may be located between the interface IF11 and the interface IF21 or aligned with the interface IF11. The third edge E34 may be located between the interface IF12 and the interface IF22 or aligned with the interface IF12.

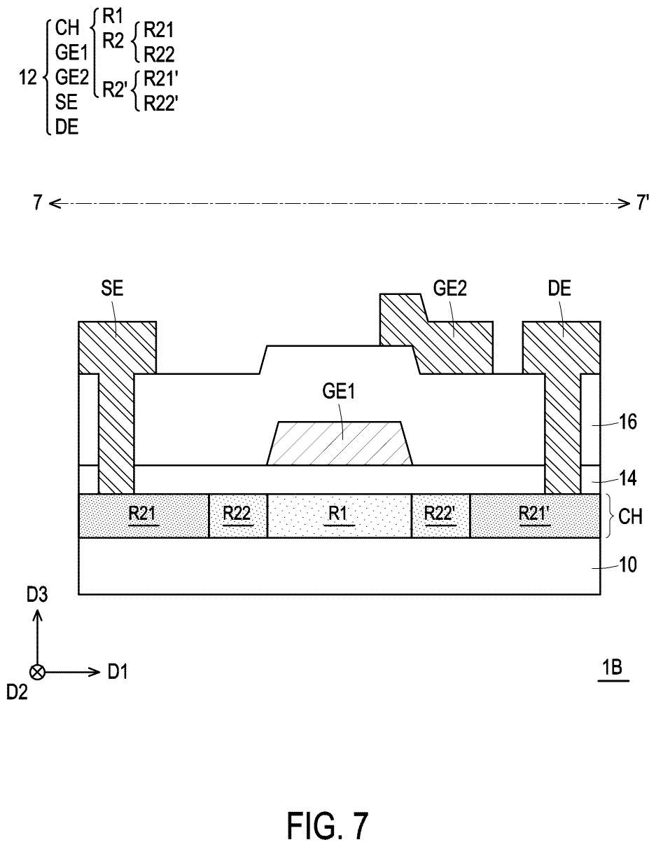

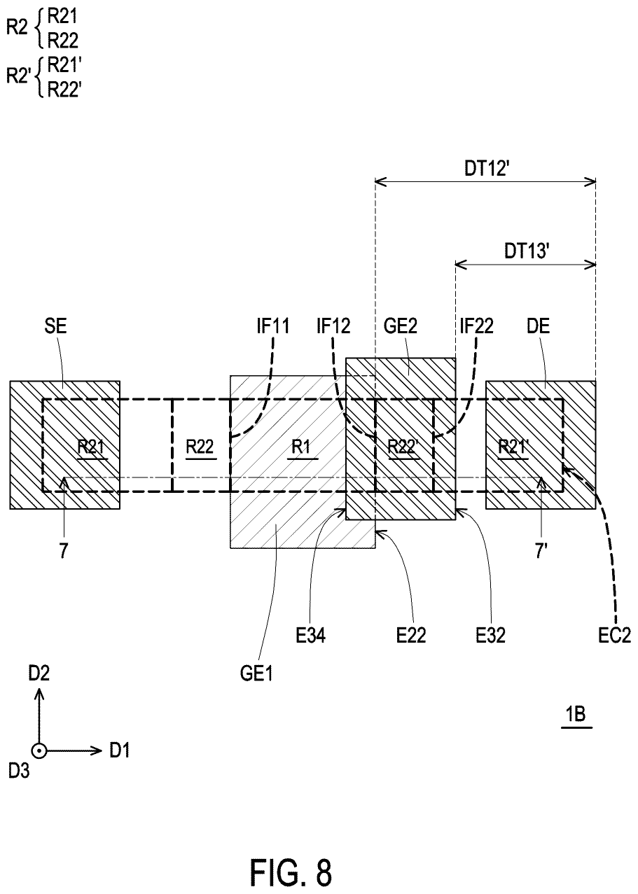

FIG. 7 is a schematic partial cross-sectional view of an electronic device according to still another embodiment of the disclosure. FIG. 8 is a schematic partial top view corresponding to the embodiment of FIG. 7. FIG. 7 may be referred for the cross-sectional view along a section line 7-7′ in FIG. 8, and FIG. 8 only schematically illustrates a semiconductor pattern, a first gate electrode, a second gate electrode, a source electrode and a drain electrode in FIG. 7.

In some embodiments, as shown in an electronic device 1B of FIG. 7 and FIG. 8, the second gate electrode GE2 may be located on a side of the first gate electrode GE1 close to the drain electrode DE.

In FIG. 8, the third edge E32 of the second gate electrode GE2 is located between the interface IF22 and the first edge EC2 of the semiconductor pattern CH, and the third edge E34 of the second gate electrode GE2 is located between the interface IF12 and the interface IF11. However, the positions of the third edge E32 and the third edge E34 of the second gate electrode GE2 are not limited thereto. In other embodiments, although not shown, the third edge E32 may be located between the interface IF12 and the interface IF22 or aligned with the interface IF22. The third edge E34 may be located between the interface IF12 and the interface IF22 or aligned with the interface IF12.

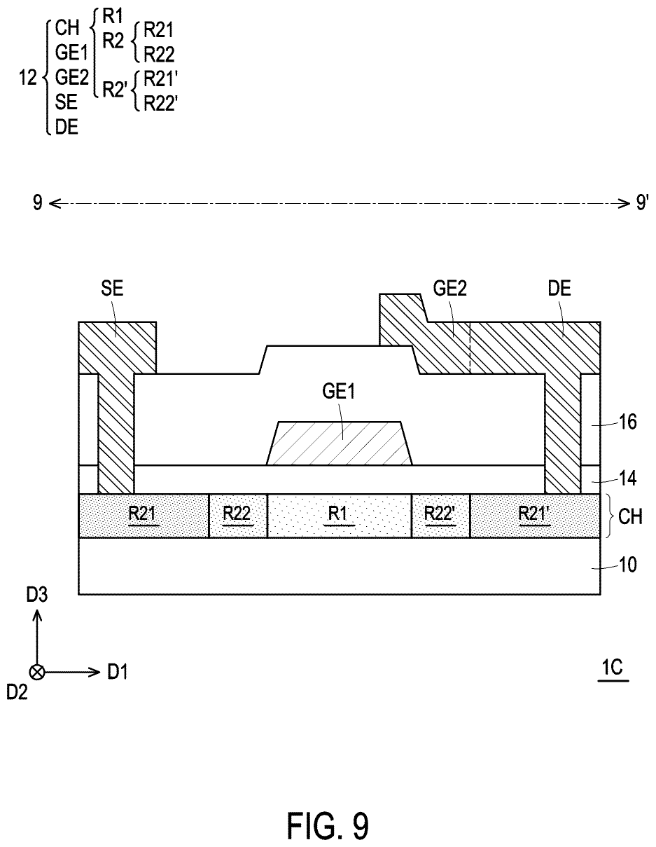

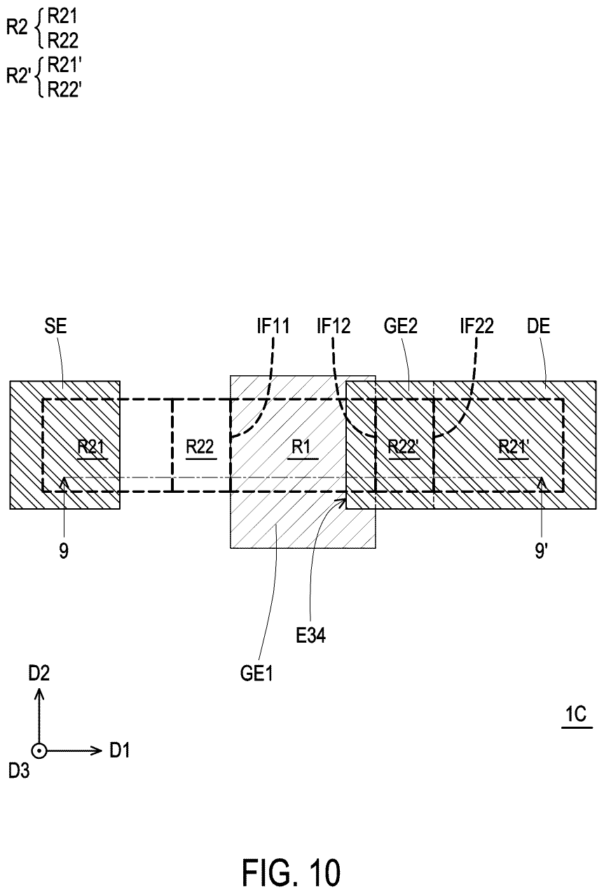

FIG. 9 is a schematic partial cross-sectional view of an electronic device according to yet another embodiment of the disclosure. FIG. 10 is a partial top view corresponding to the embodiment of FIG. 9, where FIG. 9 may be referred for the cross-sectional view along a section line 9-9′ in FIG. 10, and FIG. 10 only schematically illustrates a semiconductor pattern, a first gate electrode, a second gate electrode, a source electrode and a drain electrode of FIG. 9.

In some embodiments, as shown in an electronic device 1C of FIG. 9 and FIG. 10, the second gate electrode GE2 may be physically connected to the drain electrode DE. For example, the second gate electrode GE2 is in direct contact with the drain electrode DE, and the second gate electrode GE2 and the drain electrode DE may be formed by a same patterning process, so that there is no obvious interface between the second gate electrode GE2 and the drain electrode DE. Under such framework, in the top view, the interface IF22 may be used as an interface between the second gate electrode GE2 and the drain electrode DE.

In FIG. 10, the third edge E34 of the second gate electrode GE2 is located between the interface IF12 and the interface IF11. However, the position of the third edge E34 of the second gate electrode GE2 is not limited thereto. In other embodiments, although not shown, the third edge E34 may be located between the interface IF12 and the interface IF22 or aligned with the interface IF12.

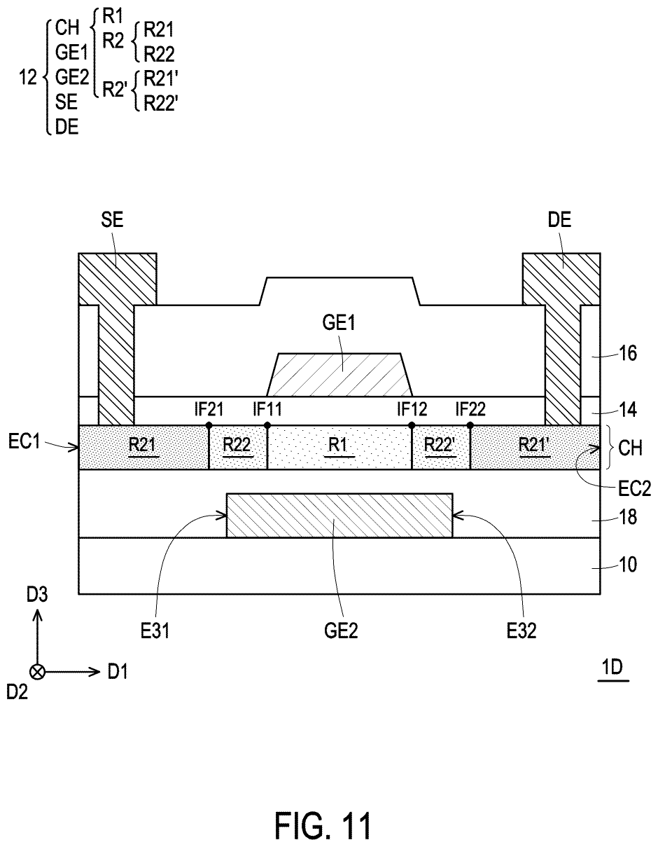

FIG. 11 to FIG. 16 are respectively schematic partial cross-sectional views of electronic devices according to other embodiments of the disclosure. Referring to FIG. 11 first, Main differences between an electronic device 1D and the electronic device 1 of FIG. 2 are described below. In the electronic device 1D, in the cross-sectional view, the second gate electrode GE2 and the first gate electrode GE1 are respectively located at two opposite sides of the semiconductor pattern CH. For example, the second gate electrode GE2 and the first gate electrode GE1 are respectively located at the two opposite sides of the semiconductor pattern CH in the third direction D3. In detail, the second gate electrode GE2 is, for example, disposed on the substrate 10. The electronic device 1D further includes a third dielectric layer 18, where the third dielectric layer 18 is disposed on the substrate 10 and the second gate electrode GE2 and is, for example, located between the second gate electrode GE2 and the semiconductor pattern CH. A material of the third dielectric layer 18 includes, for example, an organic insulating material, an inorganic insulating materials or a combination thereof.

By disposing the second gate electrode GE2 and the first gate electrode GE1 at the two opposite sides of the semiconductor pattern CH, a distance between the second gate electrode GE2 and the semiconductor pattern CH may be shortened, thereby helping to reduce an absolute value of the voltage applied to the second gate electrode GE2. Under the framework of FIG. 11, the influence of the second gate electrode GE2 on the carriers in the semiconductor pattern Ch is related to a thickness and dielectric constant of the third dielectric layer 18, and an absolute value of the voltage applied to the second gate electrode GE2 may be greater than, less than, or equal to an absolute value of the voltage applied to the first gate electrode GE1.

FIG. 3 may be referred for the top view of the second gate electrode GE2 in FIG. 11, which will not be repeated. In addition, in FIG. 11, the third edge E31 of the second gate electrode GE2 is located between the interface IF21 and the interface IF11, and the third edge E32 of the second gate electrode GE2 is located between the interface IF12 and the interface IF22. However, the positions of the third edge E31 and the third edge E32 of the second gate electrode GE2 are not limited thereto. In other embodiments, although not shown, the third edge E31 may be located between the first edge EC1 of the semiconductor pattern CH and the interface IF21 or may be aligned with the interface IF21. The third edge E32 may be located between the first edge EC2 of the semiconductor pattern CH and the interface IF22 or may be aligned with the interface IF22.

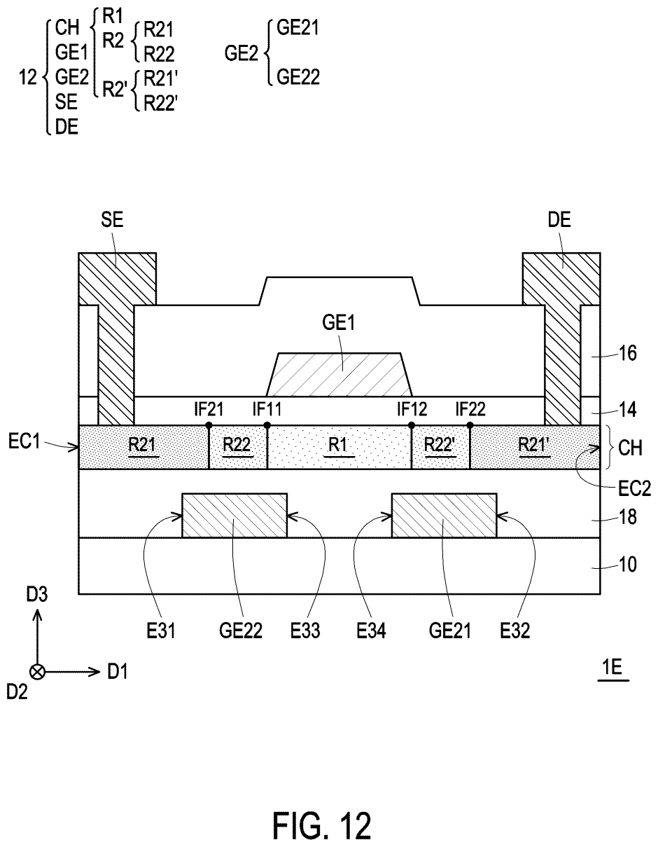

Referring to FIG. 12, main differences between an electronic device 1E and the electronic device 1D of FIG. 11 are described below. In the electronic device 1E, the second gate electrode GE2 includes a first branch portion GE21 and a second branch portion GE22. In some embodiments, although not shown in FIG. 12, the second gate electrode GE2 may further include a connection portion GE23 (referring to FIG. 6).

FIG. 5 may be referred for the top view of the second gate electrode GE2 in FIG. 12, which will not be repeated. In addition, in FIG. 12, the third edge E31 of the second gate electrode GE2 is located between the interface IF21 and the first edge EC1 of the semiconductor pattern CH, the third edge E32 of the second gate electrode GE2 is located between the interface IF22 and the first edge EC2 of the semiconductor pattern CH, the third edge E33 of the second gate electrode GE2 is located between the interface IF11 and the third edge E34 of the second gate electrode GE2, and the third edge E34 of the second gate electrode GE2 is located between the interface IF12 and the third edge E33 of the second gate electrode GE2. However, the positions of the third edge E31, the third edge E32, the third edge E33 and the third edge E34 of the second gate electrode GE2 are not limited thereto. In other embodiments, although not shown, the third edge E31 may be located between the interface IF21 and the interface IF11 or aligned with the interface IF21. The third edge E32 may be located between the interface IF12 and the interface IF22 or aligned with the interface IF22. The third edge E33 may be located between the interface IF21 and the interface IF11 or aligned with the interface IF11. The third edge E34 may be located between the interface IF12 and the interface IF22 or aligned with the interface IF12.

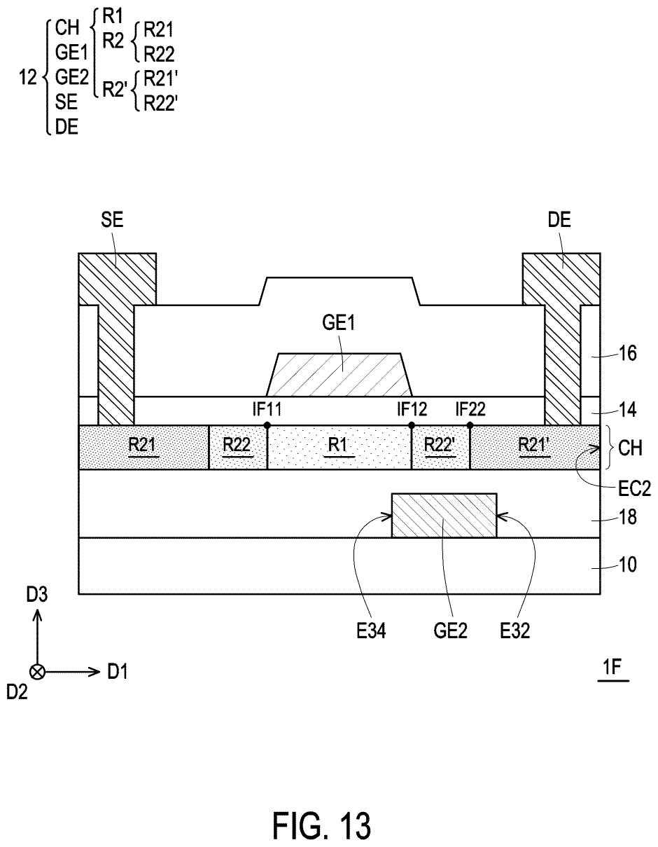

Referring to FIG. 13, main differences between an electronic device 1F and the electronic device 1E of FIG. 12 are described below. In the electronic device 1F, the second gate electrode GE2 is located on a side of the first gate electrode GE1 close to the drain electrode DE.

FIG. 8 may be referred for the top view of the second gate electrode GE2 in FIG. 13, which will not be repeated. In addition, in FIG. 13, the third edge E32 of the second gate electrode GE2 is located between the interface IF22 and the first edge EC2 of the semiconductor pattern CH, and the third edge E34 of the second gate electrode GE2 is located between the interface IF12 and the interface IF11. However, the positions of the third edge E32 and the third edge E34 of the second gate electrode GE2 are not limited thereto. In other embodiments, although not shown, the third edge E32 may be located between the interface IF12 and the interface IF22 or aligned with the interface IF22. The third edge E34 may be located between the interface IF12 and the interface IF22 or aligned with the interface IF12.

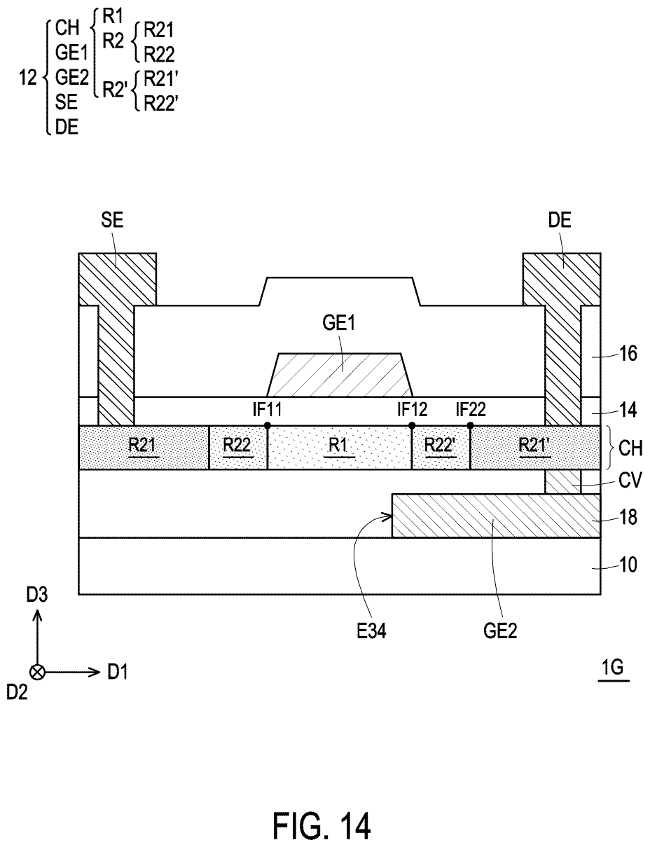

Referring to FIG. 14, main differences between an electronic device 1G and the electronic device 1F in FIG. 13 are described below. In the electronic device 1G, the second gate electrode GE2 is electrically connected to the drain electrode DE through the N-type highly doped region R21′. Taking FIG. 14 as an example, the electronic device 1G may further include a conductive via CV, where the conductive via CV electrically connects the second gate electrode GE2 to the N-type highly doped region R21′, so that the second gate electrode GE2 may be electrically connected to the drain electrode DE through the conduction via CV and the N-type highly doped region R21′.

In FIG. 14, the third edge E34 of the second gate electrode GE2 is located between the interface IF12 and the interface IF11. However, the position of the third edge E34 of the second gate electrode GE2 is not limited thereto. In other embodiments, although not shown, the third edge E34 may be located between the interface IF12 and the interface IF22 or aligned with the interface IF12.

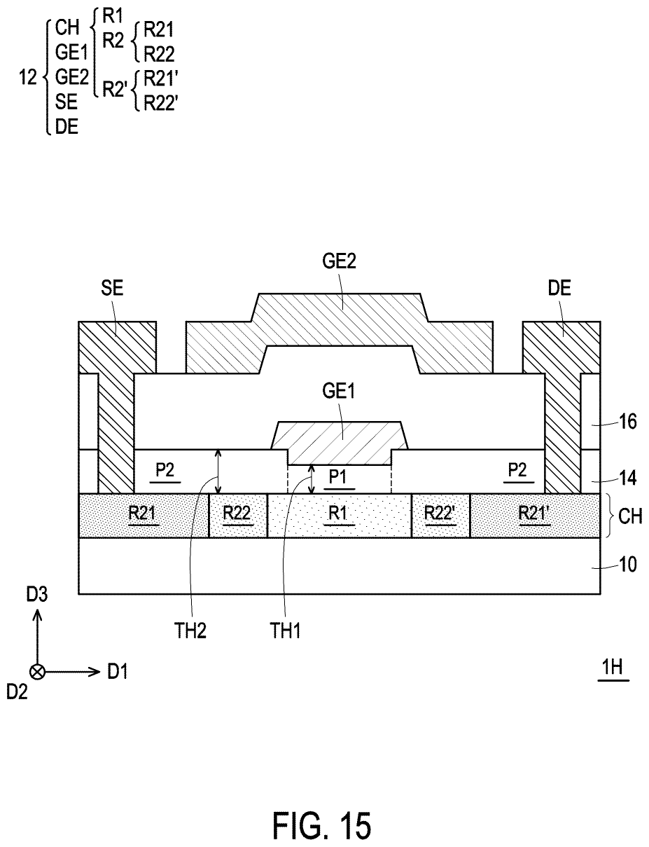

Referring to FIG. 15, main differences between an electronic device 1H and the electronic device 1 in FIG. 2 are described below. In the electronic device 1H, the first dielectric layer 14 includes a first portion P1 and a second portion P2 connected to the first portion P1 in the first direction D1, where the first portion P1 is located between the overlapping region R1 of the semiconductor pattern CH and the first gate electrode GE1, and a thickness TH1 of the first portion P1 is less than a thickness TH2 of the second portion P2. By adding a thickness of the first dielectric layer 14 corresponding to the edges of the overlapping region R1, the N-type highly doped region R21, the N-type highly doped region R21′, the N-type lightly doped region R22 and the N-type lightly doped region R22′, an electric field between the first gate electrode GE1 and the drain electrode DE may be reduced, thereby helping to reduce leakage current.

Although FIG. 15 reveals a thickness design of the first dielectric layer 14 under the structure of FIG. 2, it should be understood that this thickness design is applicable to any embodiment of the disclosure, which will not be repeated.

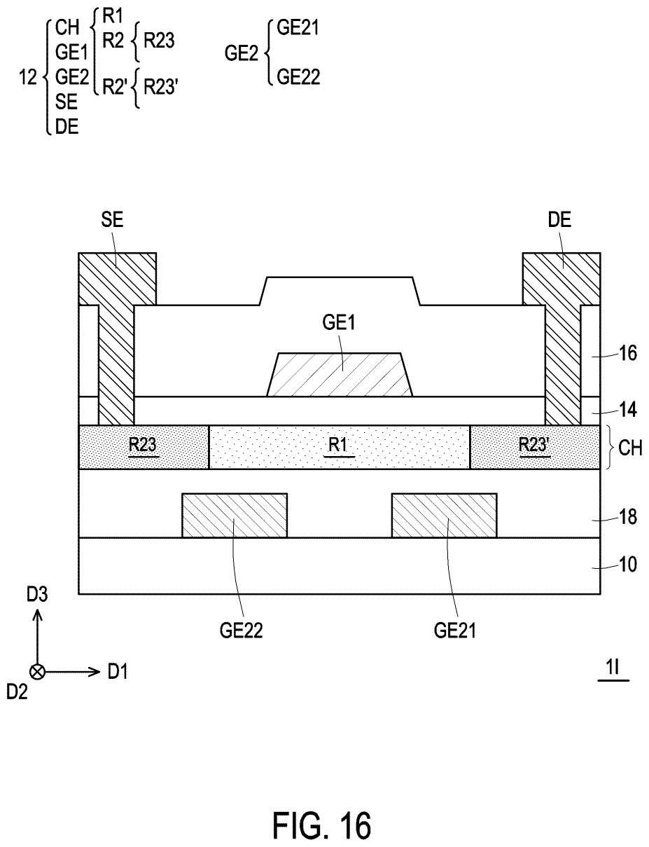

Referring to FIG. 16, main differences between an electronic device 1I and the electronic device 1E of FIG. 12 are described below. In the electronic device 1I, the electronic element 12 includes, for example, a low-temperature polycrystalline silicon P-metal-oxide-semiconductor (PMOS) thin film transistor. In the semiconductor pattern CH, the overlapping region R1 is, for example, a channel region, and the first side region R2 and the second side region R2′, for example, respectively include a P-type highly doped region, for example, the first side region R2 includes a P-type highly doped region. doped region R23, and the second side region R2′ includes a P-type highly doped region R23′.

Although FIG. 16 reveals changing a type of the semiconductor pattern under the framework of FIG. 12, it should be understood that the type of the semiconductor pattern in any embodiment of the disclosure may be changed accordingly. Alternatively, the design of the second gate electrode GE2 and/or the first dielectric layer 14 may be changed according to the aforementioned embodiment under the framework of FIG. 16. For example, the configuration of the second gate electrode GE2 in FIG. 16 may be changed with reference to FIG. 2 to FIG. 14, and/or the thickness design of the first dielectric layer 14 in FIG. 15 may be adopted.

In summary, in the embodiment of the disclosure, through the arrangement of the second gate electrode, the leakage current may be reduced without significantly reducing the conduction current of the electronic element. When electronic element is applied to high-voltage operating products, the arrangement of the second gate electrode helps to miniaturize the electronic element.

The above embodiments are only used to illustrate the technical solution of the disclosure rather than limit it; although the disclosure has been described in detail with reference to the foregoing embodiments, those with ordinary knowledge in the technical field should understand that: it is still possible to modify the technical solutions recorded in the foregoing embodiments, or to equivalently substitute some or all of the technical features; and these modifications or substitutions do not deviate from the essence of the corresponding technical solutions from the range of the technical solutions of the embodiments of the disclosure.

Although the embodiments of the disclosure and advantages thereof have been disclosed above, it should be understood that anyone with ordinary knowledge in the art may make changes, substitutions and modifications without departing from the spirit and scope of the disclosure, and the features of each embodiment may be arbitrarily mixed and replaced with each other to form other new embodiments. In addition, the protection scope of the disclosure is not limited to the processes, machines, manufacturing, material compositions, devices, methods and steps in the specific embodiments described in the specification, and anyone with ordinary knowledge in the technical field may understand the current or future developed processes, machines, manufacturing, material compositions, devices, methods, and steps from the disclosed content of the disclosure, as long as the same functions may be implemented or results may be obtained in the embodiments described herein, they may be used according to the disclosure. Therefore, the protection scope of the disclosure includes the above-mentioned processes, machines, manufacturing, material compositions, devices, methods and steps. In addition, each claim constitutes an individual embodiment, and the protection scope of the disclosure also includes combinations of each claim and embodiment. The protection scope of the disclosure is determined by the scope of the accompanying patent application.

What is claimed is:

1. An electronic device, comprising:
a substrate; and
an electronic element disposed on the substrate and comprising:
a first gate electrode;
a semiconductor pattern comprising an overlapping region, a first side region and a second side region,
wherein a portion of the semiconductor pattern overlapped with the first gate electrode is defined as the overlapping region, the first side region and the second side region are respectively connected to two opposite sides of the overlapping region in a first direction, and the first side region and the second side region respectively comprise two opposite first edges of the semiconductor pattern;
a source electrode and a drain electrode respectively electrically connected to the first side region and the second side region; and
a second gate electrode, wherein at least a portion of the second gate electrode is overlapped with the second side region of the semiconductor pattern.

2. The electronic device according to claim 1, wherein in the first direction, the first gate electrode has two opposite second edges, and the second gate electrode has two opposite third edges,
a distance between one of the third edges of the second gate electrode and one of the corresponding first edges of the semiconductor pattern is less than a distance between one of the second edges of the first gate electrode and the one of the corresponding first edges of the semiconductor pattern.

3. The electronic device according to claim 1, wherein the first side region and the second side region respectively comprise a P-type highly doped region.

4. The electronic device according to claim 1, wherein the first side region and the second side region respectively comprise an N-type highly doped region and an N-type lightly doped region located between the overlapping region and the N-type highly doped region, and the second gate electrode is at least overlapped with the N-type lightly doped region of the second side region.

5. The electronic device according to claim 4, wherein in a top view, the second gate electrode exposes a part of the N-type highly doped region of the first side region and a part of the N-type highly doped region of the second side region.

6. The electronic device according to claim 1, further comprising:
a first dielectric layer disposed between the semiconductor pattern and the first gate electrode, wherein the first dielectric layer comprises a first portion and a second portion connected to the first portion in the first direction, and the first portion is located between the overlapping region of the semiconductor pattern and the first gate electrode,
wherein a thickness of the first portion is less than a thickness of the second portion.

7. The electronic device according to claim 6, wherein in a cross-sectional view, a width of the first portion in the first direction is less than a width of the first gate electrode in the first direction.

8. The electronic device according to claim 1, wherein in a top view, the at least a portion of the second gate electrode is located between the first gate electrode and the drain electrode.

9. The electronic device according to claim 1, wherein the second gate electrode comprises a first branch portion and a second branch portion, wherein in a top view, a portion of the first branch portion is disposed between the first gate electrode and the drain electrode, and a portion of the second branch portion is disposed between the first gate electrode and the source electrode.

10. The electronic device according to claim 9, wherein the second gate electrode further comprises:
a connecting portion, wherein the first branch portion and the second branch portion of the second gate electrode are connected through the connecting portion, and in the top view, the first branch portion, the second branch portion and the connecting portion form a recess portion.

11. The electronic device according to claim 1, wherein the electronic element comprises a conductive layer, and the conductive layer comprises the second gate electrode, the source electrode and the drain electrode.

12. The electronic device according to claim 11, wherein the second gate electrode is physically connected to the drain electrode.

13. The electronic device according to claim 1, wherein in a cross-sectional view, the second gate electrode and the first gate electrode are respectively located on two opposite sides of the semiconductor pattern.

14. The electronic device according to claim 13, further comprising:
a conductive via electrically connecting the second gate electrode to the second side region.

15. The electronic device according to claim 1, wherein a voltage across the source electrode and the drain electrode is between 8 volts and 70 volts.

16. The electronic device according to claim 1, wherein the electronic element is a switching element located in an active area of the electronic device.

17. The electronic device according to claim 1, wherein the electronic element is an active element of a driving circuit located in a peripheral area of the electronic device.

18. The electronic device according to claim 1, wherein a portion of the first gate electrode is exposed by the second gate electrode.

19. The electronic device according to claim 1, wherein the first gate electrode is located between the semiconductor pattern and the second gate electrode, and the electronic device further comprises:
a first dielectric layer disposed between the semiconductor pattern and the first gate electrode; and
a second dielectric layer, wherein the first gate electrode is disposed between the first dielectric layer and the second dielectric layer, the second gate electrode, the source electrode and the drain electrode are disposed on the second dielectric layer, the source electrode penetrates through the first dielectric layer and the second dielectric layer and is electrically connected to the first side region, and the drain electrode penetrates through the first dielectric layer and the second dielectric layer and is electrically connected to the second side region.

20. The electronic device according to claim 1, wherein the semiconductor pattern is located between the first gate electrode and the second gate electrode, and the electronic device further comprises:
a first dielectric layer disposed between the semiconductor pattern and the first gate electrode;
a second dielectric layer, wherein the first gate electrode is disposed between the first dielectric layer and the second dielectric layer, the source electrode and the drain electrode are disposed on the second dielectric layer, the source electrode penetrates through the first dielectric layer and the second dielectric layer and is electrically connected to the first side region, and the drain electrode penetrates through the first dielectric layer and the second dielectric layer and is electrically connected to the second side region; and
a third dielectric layer, wherein the second gate electrode is disposed between the third dielectric layer and the substrate.
